(19) United States
(12) Patent Application Publication
(10) Pub. No.: US 2010/0059789 A1
(43) Pub. Date: Mar. 11, 2010

(54) NITRIDE SEMICONDUCTOR LIGHT-EMITTING DEVICE AND METHOD FOR FABRICATING THEREOF

(76) Inventor: Yeon-Jo Choi, Suwon-si (KR)

Correspondence Address: SHERR & VAUGHN, PLLC, 620 HERNDON PARKWAY, SUITE 320, HERNDON, VA, 20170, US

(21) Appl. No.: 12/500,401

(22) Filed: Jul. 9, 2009

(30) Foreign Application Priority Data
Sep. 11, 2008 (KR) 10-2008-0089735

(51) Int. Cl. H01L 33/00

(52) U.S. Cl. 257/103; 257/99; 438/46; 438/597; 257/E33.063; 257/E33.013; 257/E21.002

(57) ABSTRACT

Disclosed is a nitride semiconductor light-emitting device, including a substrate, a nitride semiconductor layer including a first conductive layer, an active layer and a second conductive layer located on the substrate, a first electrode formed on the first conductive layer, and a second electrode formed on the second conductive layer, wherein a pattern having one or more protrusions formed at a predetermined interval and concave portions resulting from depression of upper surfaces of the protrusions to a predetermined depth is formed on the surface of the substrate which abuts with the first conductive layer. A method of fabricating the nitride semiconductor light-emitting device is also provided. When the substrate having a pattern with protrusions and concave portions is used, higher light extraction efficiency can be obtained.

### TECHNICAL FIELD

The present invention relates to a nitride semiconductor light-emitting device and method of fabricating the same, and more particularly to a nitride semiconductor light-emitting device in which a sapphire substrate configured to grow a nitride semiconductor layer is patterned and then the nitride semiconductor layer is formed thereon, thus reducing crystal defects and improving light output, and to a method of fabricating the same.

### BACKGROUND ART

Generally, a base substrate is determined depending on the type of thin film to be grown thereon. Defects in the crystals to be grown may occur due to the differences in lattice constant between the base substrate and the thin film to be grown thereon, and such defects act to impede the effective growth of an epitaxial layer.

Accordingly, by using a sapphire substrate for AlGaP, InGaN, AlGaN, GaN, GaP/AlP or a heterojunction structure, an InP substrate for InP, InGaAs, GaAs or AlGaAs, or a GaAs substrate for GaAs, GaAlAs, InGaP or InGaAlP, a semiconductor growing process through MOCVD or MBE may be performed.

In the case of using GaN as a nitride semiconductor, a sapphire substrate may be mainly used because the lattice constant of sapphire is similar to that of GaN.

When a predetermined amount of power is applied to a sapphire substrate having nitride grown thereon, light is emitted. As such, if the same nitride structure is grown on a patterned sapphire substrate, light output is reported to be superior compared to when nitride is grown on a typical planar substrate.

Depending on the structure of the pattern, light output after the growth of nitride may vary. Constant efforts to obtain much higher light output compared to conventional patterns have been made to date.

FIG. 1 shows the general structure of a Group III nitride compound semiconductor using a sapphire substrate.

Formed on the sapphire substrate 11 is an n-GaN layer 12, after which an active layer 13, a p-GaN layer 14 and a p-electrode layer 15 are sequentially formed on a portion of the upper surface of the n-GaN layer 12. Also, an n-electrode layer 16 is formed on the other portion of the upper surface of the n-GaN layer 12 where the above active layer 13 is not formed. Typically, in a light-emitting device (LED), how much of the light generated in the inner active layer is efficiently extracted to the outside is regarded as important.

With the goal of efficiently extracting light generated in the longitudinal direction of the sapphire substrate and the active layer, attempts to form a transparent electrode or a reflective layer have been made.

However, a considerable amount of light generated in the active layer travels in a transverse direction. Thus, in order to extract such light in a longitudinal direction, for example, attempts have been made to incline the sidewall of the laminate structure of a semiconductor device at a predetermined angle so that the above sidewall is formed with a reflective surface, but this causes problems in terms of processing and costs.

Further, in order to improve the light output of the Group III nitride compound semiconductor LED using the sapphire substrate, a flip chip device may be adopted. In this case, light extraction efficiency does not go over about 40% due to the difference in refractive index between the GaN and the sapphire substrate.

Also, FIG. 2 illustrates an LED obtained by processing the surface of a sapphire substrate 21, thus forming an uneven structure, and then forming semiconductor crystal layers including an active layer 22 thereon. In this way, when the uneven refractive interface is formed under the active layer 22, part of the light traveling in a transverse direction which disappears in the device may be extracted to the outside.

In the case where a Group III nitride compound semiconductor is formed on the sapphire substrate 21, dislocation occurs due to a lattice constant incongruity between the sapphire substrate 21 and the Group III nitride compound semiconductor. In order to prevent the lattice constant incongruity, as shown in FIG. 3, the surface of the sapphire substrate 21 is formed with an uneven structure, and a GaN layer 23 is then formed thereon. A process of forming an LED on the sapphire substrate having the uneven structure is schematically shown in FIG. 4.

Specifically, in the case where the GaN layer 23 is formed on the sapphire substrate 21 having the uneven structure as shown in FIG. 4-a, GaN facets 24 are grown on the upper surfaces of protrusions of the uneven structure and in the spaces between protrusions of the uneven structure as shown in FIG. 4-b, thereby obtaining a planarized GaN layer 23 as shown in FIG. 4-c. Thereafter, an active layer 22 is formed on the planarized GaN layer 23, thus completing a light emitting diode as shown in FIG. 4-d.

In the case where the semiconductor crystal layer is grown using such a patterned sapphire substrate, planarization follows facet growth on the pattern structure, undesirably causing problems in which the layer should be regrown to a considerable thickness for such planarization.

Further, there is disclosed a structure for preventing propagation of threading dislocation by processing a sapphire substrate thus forming an uneven structure having trenches and mesas and then growing a Group III nitride compound semiconductor layer on the upper surfaces of the mesas and the sidewalls of the trenches (WO2001-69663). However, this structure is disadvantageous because voids are formed under the uneven structure, and the Group III nitride compound semiconductor layer should be formed to be relatively thick to planarize the growth layer.

In addition, methods of reducing a defect density upon regrowth of the semiconductor crystal layer on the sapphire substrate may include ELOG and PENDEO. However, in the case of the ELOG method, an additional mask layer is required, and in the case of the PENDEO method, voids are formed in the interface with the substrate, undesirably lowering light extraction efficiency.

Hence, there is recently proposed an LED as shown in FIG. 5 in which hemispherical protrusions 32 are formed on the surface of a substrate 31, and the entire surface of the hemispherical protrusions 32 is curved without distinction of upper surfaces and sidewalls and there are no flat portions.

However, the above LED is problematic in that it is difficult to grow the Group III nitride compound semiconductor on the hemispherical protrusions 32, and also, the planarized GaN layer 33 may be formed without facet growth, and thus the thickness of the planarized GaN layer 33 may be relatively reduced.

Therefore, the conventional substrate pattern having a bar having a semicircular section, a hemispherical protrusion, a protrusion having a ladder-shaped section, a protrusion having a triangular section, a pyramidal protrusion and the like is limited in terms of light extraction efficiency.

### DISCLOSURE

### [Technical Problem]

Accordingly, the present invention has been made keeping in mind the above problems encountered in the related art, and provides a nitride semiconductor LED and a method of fabricating the same, in which the pattern structure of a substrate is improved to thus achieve much higher light extraction efficiency.

### [Technical Solution]

According to an aspect of the present invention, a nitride semiconductor LED includes a substrate, a nitride semiconductor layer including a first conductive layer, an active layer and a second conductive layer located on the substrate, a first electrode formed on the first conductive layer, and a second electrode formed on the second conductive layer, wherein a pattern having one or more protrusions formed at a predetermined interval and concave portions resulting from depression of upper surfaces of the protrusions to a predetermined depth is formed on the surface of the substrate which abuts with the first conductive layer.

According to a first preferred feature of the present invention, the substrate may be a sapphire substrate.

According to a second preferred feature of the present invention, the protrusions and the concave portions may have respective predetermined curvatures.

According to a third preferred feature of the present invention, the protrusions may have a curvature smaller or greater than that of the concave portions.

According to a fourth preferred feature of the present invention, the concave portions may have a depth depressed to be less or greater than a height of the protrusions.

According to a fifth preferred feature of the present invention, the first conductive layer and the second conductive layer may include any one selected from among binary nitrides, including GaN, AlN and InN, ternary nitrides, and quaternary nitrides.

According to another aspect of the present invention, a method of fabricating a nitride semiconductor LED composed of a substrate, a nitride semiconductor layer including a first conductive layer, an active layer and a second conductive layer located on the substrate, a first electrode formed on the first conductive layer, and a second electrode formed on the second conductive layer includes patterning a surface of the substrate using a mask, baking the substrate having the pattern at a predetermined temperature, thus forming protrusions and concave portions in the pattern, removing the mask from the pattern having the protrusions and the concave portions through etching, forming the first conductive layer, the active layer, and the second conductive layer on the substrate having the protrusions and the concave portions, and forming the first electrode layer and the second electrode layer.

According to a first preferred feature of the present invention, the mask may be any one selected from among photoresists, SiO2, SixNx, and metal thin films.

According to a second preferred feature of the present invention, removing the mask may be conducted through dry etching or wet etching.

According to a further aspect of the present invention, a nitride semiconductor LED includes a substrate and a nitride semiconductor layer grown on the substrate, wherein a pattern having one or more protrusions formed at a predetermined interval and concave portions resulting from depression of upper surfaces of the protrusions to a predetermined depth is formed on the surface of the substrate which abuts with a first conductive layer.

### [Advantageous Effects]

According to the present invention, a sapphire substrate is patterned such that protrusions and concave portions are formed, thus realizing higher light extraction efficiency compared to conventional pattern structures having hemispherical, corrugated, triangular shapes and the like.

### DESCRIPTION OF DRAWINGS

FIG. 1 is a cross-sectional view showing a general structure of a Group III nitride compound semiconductor LED using a sapphire substrate;

FIG. 2 is a cross-sectional view showing a Group III nitride compound semiconductor LED formed on a sapphire substrate according to a conventional technique;

FIGS. 3 and 4 are schematic cross-sectional views showing a process of forming the LED on the substrate having an uneven structure according to the conventional technique;

FIG. 5 is of schematic cross-sectional views showing a process of forming an LED on a substrate having a hemispherical pattern according to another conventional technique;

FIG. 6 is a cross-sectional view showing the pattern of a substrate of a nitride semiconductor LED according to the present invention;

FIG. 7 is of cross-sectional views showing examples of the pattern of the substrate according to the present invention;

FIG. 8 is a perspective photograph and a top plan photograph showing the pattern of the substrate according to the present invention;

FIG. 9 is a cross-sectional view showing the nitride semiconductor LED according to the present invention;

FIG. 10 is of cross-sectional views showing a process of fabricating the nitride semiconductor LED according to the present invention; and

FIG. 11 is of graphs showing light output of the nitride semiconductor LEDs according to the present invention and the conventional techniques.

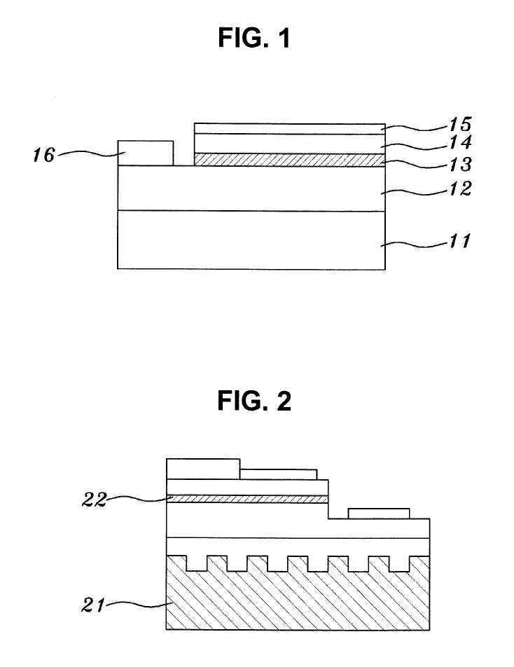

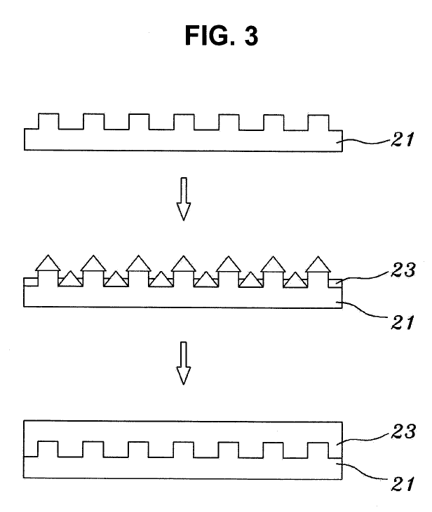

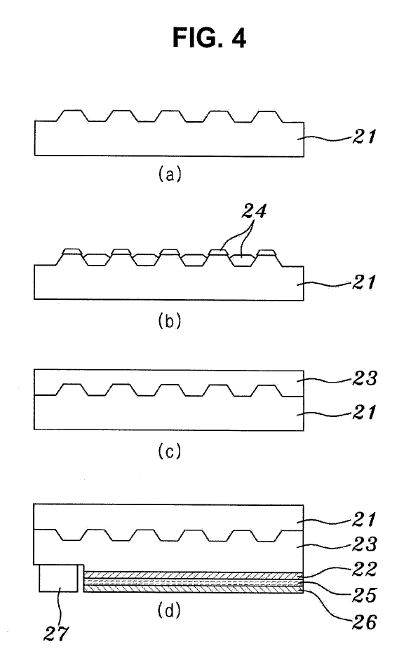

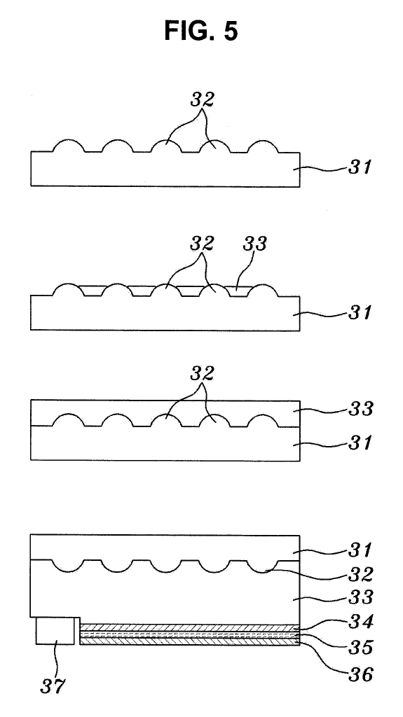

### MODE FOR INVENTION

Hereinafter, a detailed description will be given of a nitride semiconductor LED and a fabrication method thereof according to a preferred embodiment of the present invention with reference to the appended drawings.

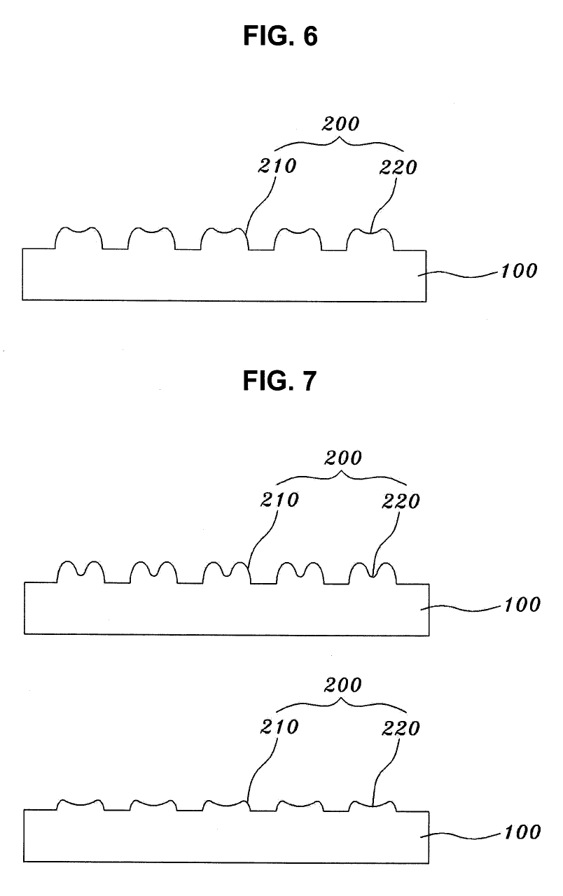

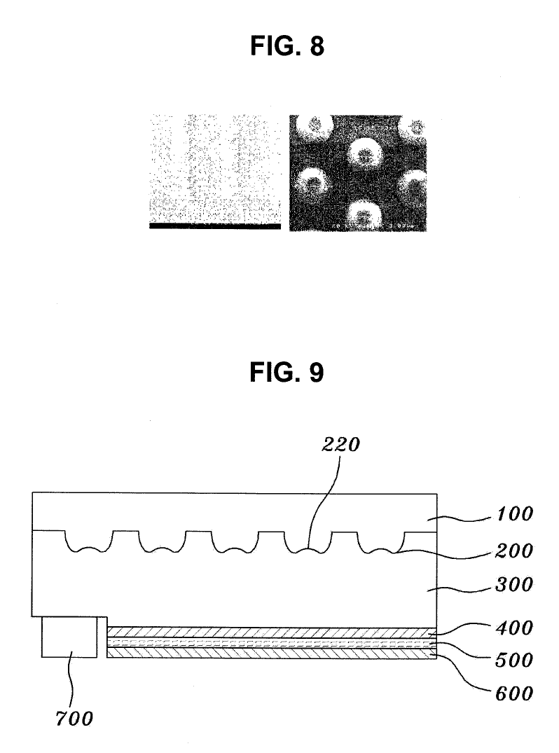

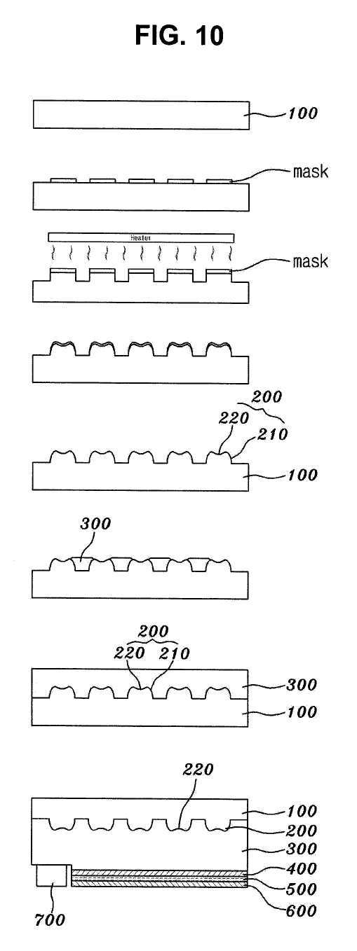

FIG. 6 is a cross-sectional view showing the pattern of the substrate of the nitride semiconductor LED according to the present invention, FIG. 7 is of cross-sectional views showing examples of the pattern of the substrate according to the present invention, FIG. 8 is a perspective photograph and a top plan photograph showing the pattern of the substrate according to the present invention, FIG. 9 is a cross-sectional view showing the nitride semiconductor LED according to the present invention, and FIG. 10 is of cross-sectional views showing a process of fabricating the nitride semiconductor LED according to the present invention.

The nitride semiconductor LED according to the present invention is composed of a substrate 100, a nitride semiconductor layer including a first conductive layer, an active layer and a second conductive layer located on the substrate, a first electrode formed on the first conductive layer, and a second electrode formed on the second conductive layer, wherein a pattern having protrusions and concave portions resulting from depression of the upper surfaces of the protrusions to a predetermined depth is formed on the surface of the substrate on which the first conductive layer is grown.

The substrate 100 may include a sapphire substrate adapted for a nitride semiconductor LED. Alternatively, silicon carbide (SiC) may be used. In the present invention, the sapphire substrate is illustrative.

On the sapphire substrate 100, a pattern 200 is formed to increase light output. In the present invention, the pattern 200 having protrusions 210 and concave portions 220 is provided.

In order to form such a pattern, an etching mask is used, and the mask may include a photoresist, SiO2, SixNx, metal thin films, etc. To pattern the substrate, a photoresist is particularly useful. To form a predetermined pattern, a photosensitive process is conducted using an exposure system. The thickness of the photoresist for the mask may vary depending on a desired etching depth of the substrate.

The portion of the substrate 100 which is not covered with the mask having a predetermined pattern is etched. This etching process may be performed in the same manner as in photolithography, and a detailed description thereof is omitted.

Thereafter, the substrate is heated to a predetermined temperature through baking, so that the protrusions of the substrate covered with the photoresist are depressed, thus forming concave portions, resulting in the pattern 200. As such, the pattern structure may vary depending on the temperature and time of the baking process.

In a preferred embodiment of the present invention, the baking may be performed at 100˜140° C. for 1˜5 min.

As shown in FIG. 7, the curvature of the protrusions 210 may be larger or smaller than that of the concave portions 220, and the depth of the concave portions 220 may be greater than the height of the protrusions. The pattern 200 formed on the substrate may be regular or irregular.

The substrate 100 having the pattern 200 may be formed by dry etching or wet etching the substrate and the photoresist together, thus forming the pattern 200 having the protrusions 210 and the concave portions 220. As such, depending on the etching conditions including the etching time and the etchant or the etching gas used, the shape of the pattern having the protrusions 210 and the concave portions 220 may change. In the case where the substrate is subjected to dry etching, examples of the etching gas include Cl gases such as Cl2, BCl3 and so on.

The number of each of protrusions 210 and concave portions 220 of the pattern 200 formed on the substrate 100 may be one or more.

The above pattern 200 has an enlarged surface area thanks to the formation of the concave portions 220, thus exhibiting effects different from those of a conventional substrate having a hemispherical pattern. The hemispherical pattern structure has a limited area for growing nitride.

However, because the pattern of the present invention has the protrusions 210 and the concave portions 220, the entire surface thereof is curved, and also, the protrusions and the concave portions each have a curvature greater than zero, thereby realizing a much larger area. Hence, the area of the Group III nitride compound semiconductor which is grown on the protrusions 210 and concave portions 220 may be enlarged, leading to increased efficiency.

On the substrate thus prepared, the first conductive layer (n-GaN layer) 300, the active layer 400 and the second conductive layer (p-GaN layer) 500 are grown. Then, the first electrode (p-electrode layer) 600 is formed on the second conductive layer, and the second electrode (n-electrode layer) 700 is formed on a portion of the first conductive layer where the active layer and the second conductive layer are not formed, thereby fabricating the nitride LED.

FIG. 9 is a cross-sectional view showing the flip chip LED including the substrate 100 having the pattern 200 which has the protrusions 210 and the concave portions 220 according to the present invention. As shown in this drawing, on the substrate 100 having pluralities of curved protrusions 210 and concave portions 220, the n-GaN layer 300 is formed, the active layer 400 is formed on the n-GaN layer, and then the p-GaN layer 500 and the p-electrode layer 600 are sequentially formed.

Further, the n-electrode layer 700 is formed on the portion of the n-GaN layer 300 having no active layer 400. The structures, except for that of the substrate 100, are similar to that of the Group III nitride compound semiconductor LED.

The Group III nitride compound semiconductor formable on the substrate 100 is not limited to GaN but includes binary nitrides such as AlN or InN, ternary nitrides, and quaternary nitrides.

The substrate 100 having the pattern 200 according to the present invention can be adequately applied to various compound semiconductor LEDs, as well as the nitride semiconductor LED.

In addition, the method of fabricating the nitride semiconductor LED according to the present invention is described below.

To form the pattern 200 having pluralities of curved protrusions 210 and concave portions 220 on the surface of the sapphire substrate 100, a photoresist is applied on the planar sapphire substrate 100, after which exposure and development are conducted, thus forming a predetermined pattern.

Next, the portion of the substrate 100 having no pattern is etched such that a predetermined pattern is formed on the substrate, after which hard baking is performed. The baking process may be carried out under various conditions depending on desired pattern shape. Typically, the baking process may be performed at 100˜140° C. for 1˜5 min.

Specifically, the substrate 100 is subjected to dry etching. As such, etching gas, operation pressure and operation power should be appropriately controlled. For example, the etching gas may be BCl3, the operation pressure may be set to 1 mTorr, and the operation power may be set to 1100 W/500 W.

Next, the mask is removed from the pattern through etching, and thereby, the pattern 200 having the protrusions and the concave portions is finally formed on the substrate 100. Thereafter, the n-GaN layer 300, the active layer 400, the p-GaN layer 500, the p-electrode layer 600, and the n-electrode layer 700 necessary for the fabrication of an LED are formed. The n-electrode layer is formed after exposure of the first conductive layer through etching of the p-electrode layer, the second conductive layer and the active layer.

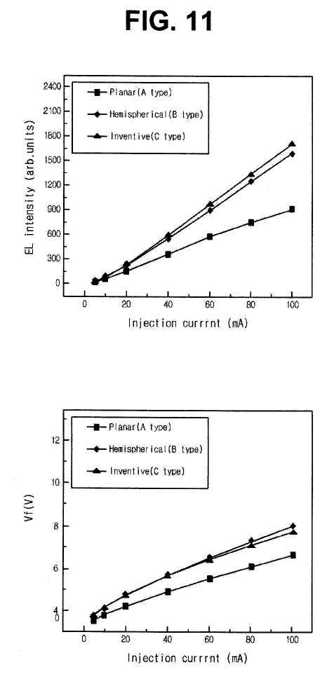

FIG. 11 is of graphs showing the light output of the nitride semiconductor LEDs according to the present invention and the conventional techniques.

Type A uses a planar substrate, type B uses a substrate having a hemispherical pattern, and type C uses the substrate according to the present invention. As is apparent from the graphic results, type B in which the LED was formed on the substrate having the hemispherical pattern had light output increased by about 70% compared to type A in which the LED was formed on the planar substrate. Type C in which the LED was formed on the substrate having the pattern with the protrusions and the concave portions had light output increased by about 90% or more compared to type A, and also light output increased by about 10% or more compared to type B.

Further, type B in which the LED was formed on the substrate having the hemispherical pattern had the VF value increased by about 23% compared to type A. Type C according to the present invention had the VF value increased by about 18% compared to type A, and the VF value reduced by about 10% or more compared to type B.

In this way, when the substrate having the protrusions 210 and the concave portions 220 is used, superior light efficiency and VF value can be exhibited, compared to when using the conventional substrates having the uneven or hemispherical pattern.

In the protrusions of the pattern of the substrate according to the present invention, the concave portions are formed to a predetermined depth, so that the area of the nitride growing on the pattern can be increased, leading to much higher light extraction efficiency.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1-10. (canceled)

11. A light-emitting device comprising:
a substrate;
a first conductive layer formed over the substrate;
an active layer formed over the first conductive layer;
a second conductive layer formed over the active layer;
a first electrode formed over the second conductive layer; and
a second electrode formed over the first conductive layer,
wherein the substrate has a plurality of patterns formed spaced apart from each other on a surface thereof, each pattern having at least one protrusion and at least one concave portion.

12. The light-emitting device of claim 11, wherein the substrate comprises a sapphire substrate.

13. The light-emitting device of claim 11, wherein the at least one protrusion and the at least one concave portion have respective predetermined curvatures.

14. The light-emitting device of claim 11, wherein the at least one protrusion has a curvature smaller than the curvature of the at least one concave portion.

15. The light-emitting device of claim 11, wherein the at least one protrusion has a curvature greater than the curvature of the at least one concave portion.

16. The light-emitting device of claim 11, wherein the at least one concave portion has a depth greater than a height of the at least one protrusion.

17. The light-emitting device of claim 11, wherein the first conductive layer and the second conductive layer each comprise one of a binary nitride material, a ternary nitride material and a quaternary nitride material.

18. The light-emitting device of claim 17, wherein the binary nitride material is one selected from a group consisting of GaN, AlN and InN.

19. A semiconductor light-emitting device comprising:
a substrate having a plurality of patterns formed on a surface thereof, each pattern having a plurality of protrusions and a plurality of concave portions;
a first conductive layer composed of a first doped material formed over and contacting the substrate including the patterns;
an active layer formed over and contacting the first conductive layer;
a second conductive layer composed of a second doped material formed over and contacting the active layer;
a first electrode formed over and contacting the second conductive layer; and
a second electrode formed over and contacting the first conductive layer.

20. The semiconductor light-emitting device of claim 19, wherein the first conductive layer and the second conductive layer each comprise one of a doped binary nitride material, a doped ternary nitride material and a doped quaternary nitride material.

21. The semiconductor light-emitting device of claim 20, wherein the doped binary nitride material is one selected from a group consisting of GaN, AlN and InN.

22. The semiconductor light-emitting device of claim 19, wherein the first electrode comprises a p-type electrode layer.

23. The semiconductor light-emitting device of claim 22, wherein the second electrode comprises an n-type electrode layer.

24. The semiconductor light-emitting device of claim 19, wherein the protrusion comprises a plurality of protrusions and the concave portion comprises a plurality of concave portions.

25. A method of fabricating a light-emitting device comprising:
forming a mask over the surface of a substrate; and then
performing a first etching process on the surface of the substrate; and then
performing a heat treatment on the substrate after performing the first etching process to form a plurality of patterns on the surface of a substrate, wherein each pattern has at least one protrusions and at least one concave portion; and then
sequentially forming a first conductive layer, an active layer, a second conductive layer and a first electrode layer over the substrate including the patterns; and then
performing a second etching process on the active layer, the second conductive layer and the first electrode layer to expose a portion of the uppermost surface of the first conductive layer; and then
forming the second electrode layer over the exposed portion of the first conductive layer.

26. The method of claim 25, wherein the protrusion comprises a plurality of protrusions and the concave portion comprises a plurality of concave portions.

27. The method of claim 25, wherein the light-emitting device comprises a semiconductor light-emitting device.

28. The method of claim 25, wherein the at least one protrusion has a curvature smaller than the curvature of the at least one concave portion.

29. The method of claim 25, wherein the at least one concave portion has a depth greater than a height of the at least one protrusion.

30. The method of claim 25, wherein the first conductive layer and the second conductive layer each comprise one of a binary nitride material, a ternary nitride material and a quaternary nitride material.
